(19) United States
(12) Patent Application Publication
(10) Pub. No.: US 2011/0079179 A1
(43) Pub. Date: Apr. 7, 2011

(54) LIQUID MATERIAL VAPORIZER AND FILM DEPOSITION APPARATUS USING THE SAME

(75) Inventor: Shigeyuki Okura, Yamanashi-Ken (JP)

(73) Assignee: TOKYO ELECTRON LIMITED, Tokyo-To (JP)

(21) Appl. No.: 12/935,674

(22) PCT Filed: Mar. 24, 2009
(86) PCT No.: PCT/JP2009/055805

§ 371 Date: Dec. 7, 2010

(30) Foreign Application Priority Data
Mar. 31, 2008 (JP) 2008-091545

(51) Int. Cl. C23C 16/455; B05B 1/24

(52) U.S. Cl. 118/726; 392/394

(57) ABSTRACT

The present invention is a liquid material vaporizer comprising a liquid-material supply part configured to make a liquid material into a droplet state and to discharge the same, and a vaporizing part configured to vaporize the liquid material in a droplet state so as to generate a source gas, the vaporizing part including: an inlet port to which the liquid material in a droplet state is introduced from the liquid-material supply part; a housing body of a bottomed tubular shape, the housing body having an opening end on a side of the inlet port; a columnar block having a flange for closing the opening end of the housing body, the columnar block being fitted in the housing body in such a manner that a gap serving as a vaporizing path is defined between the columnar block and an inside surface of the housing body; a breathable mist trap member disposed in the vaporizing path formed between the inside surface of the housing body and an outside surface of the columnar block, in such a manner that the mist trap member is in contact with the inside surface of the housing body and covers the outside surface of the columnar block; a heating part disposed to cover the housing body, the heating part being configured to heat the mist trap member through the housing body; a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state, which has been introduced from the inlet port, toward an inside surface of the mist trap member; and an outlet port disposed in a bottom part of the housing body, the outlet port being configured to deliver a source gas generated by the mist trap member that vaporizes the liquid material in a droplet state in the vaporizing path.

### FIELD OF THE INVENTION

The present invention relates to a liquid material vaporizer configured to vaporize a liquid material so as to generate a source gas, and a film deposition apparatus using the same.

### BACKGROUND ART

As a method of depositing a dielectric film, a metal film, or a semiconductor film, on a surface of a substrate to be processed such as a semiconductor substrate or a glass substrate, a chemical vapor deposition (CVD) method is known in which an organic source gas such as an organic metal compound is supplied to a film deposition chamber in which the substrate to be processed is placed, and the organic source gas is reacted with another gas such as oxygen or ammonia so as to deposit a film. An organic material used in such a CVD method is generally liquid or solid at normal temperatures. Thus, a vaporizer for vaporizing the organic material is needed.

Generally, the organic material is previously liquidized into a liquid material by means of a solvent, and is then introduced into a vaporizer. As a conventional vaporizer for vaporizing such a liquid material to generate a source gas, there is a vaporizer having a vaporizing surface with a number of holes in a vaporizing chamber. In the vaporizer, while the vaporizing surface is being heated by a resistance heater, the liquid material is discharged to form liquid droplets (mist) thereof from a nozzle, and the liquid material in a droplet state is sprayed onto the vaporizing surface with the aid of a flow of a carrier gas, so as to achieve vaporization.

In such a vaporizer, in order to improve a vaporization efficiency, it is preferable to make the liquid material into minute droplets as much as possible, and to spray the minute droplets onto the vaporizing surface. However, the smaller the diameter of the droplet is, the more likely the droplet are to pass through the holes of the vaporizing surface without contacting the same. The droplet, which has passed through the vaporizing surface without being vaporized, flows into the film deposition chamber with the flow of the carrier gas, resulting in generation of particles. For example, when the liquid material in a droplet state, which could not be vaporized, flows into the film deposition chamber where oxygen remains, the droplets of the liquid material are oxidized to generate fine particles. These particles may adhere to a substrate, which invites abnormal film deposition and/or give an adverse effect on a film quality.

Thus, the source gas generated by the vaporizer is conventionally supplied into the film deposition chamber via a filter having minute holes. By heating the filter by a resistance heater or the like, the liquid material in a droplet state that could not be vaporized, which is contained in the source gas reaching the filter, can be vaporized by the filter. FIGS. 13 and 14 show examples of such a conventional filter apparatus.

A conventional filter apparatus 10 shown in FIG. 13 includes a substantially cylindrical housing 12 having, in one end thereof, an inlet port 14 to which a source gas is introduced, and an outlet port 16 in the other end thereof. An inside space of the housing 12 is divided into an outside space in communication with the inlet port 14 and an inside space in communication with the outlet port 16, by a mist trap member 20 formed of a substantially cylindrical breathable member 18. A heater 22 is disposed to surround the housing 12.

In such a filter apparatus 10, when the heater 22 is turned on, the housing 12 is heated. The breathable member 18 is also heated by a heat conducted from a downstream end 18a in contact with the housing 12. Under this state, when a source gas is introduced into the filter apparatus 10 from the inlet port 14, the source gas passes through the heated breathable member 18 from the outside space thereof to the inside space, so as to be delivered from the outlet port 16.

Another conventional filter apparatus 30 shown in FIG. 14 includes a substantially cylindrical housing 32 having, in one end thereof, an inlet port 33 to which a source gas is introduced, and an outlet port 36 in the other end thereof. A substantially discoid breathable member 34 is disposed on a larger-diameter part 38 of the housing 32 so as to separate an upstream space and a downstream space from each other. A heater 42 is disposed to surround the housing 32.

In such a filter apparatus 30, when the heater 42 is turned on, the housing 32 is heated. The breathable member 34 connected to an inner wall of the housing 32 is also heated by a heat conducted from the housing 32. Under this state, when a source gas is introduced from the inlet port 33 of the housing 32, the source gas passes through the heated breathable member 34 from the upstream space to the downstream space, so as to be delivered from the outlet port 36 of the housing 32.

Due to the conventional filter apparatus that is arranged between the vaporizer and the film deposition chamber, even when the vaporization efficiency of the vaporizer itself is more or less insufficient, it is possible to prevent the liquid material in a droplet state, which could not be vaporized, from flowing into the film deposition chamber as it is.

In addition, in order to improve the vaporization efficiency, a vaporizer may include a breathable member having minute holes such as a solid filler having narrow holes or a porous body. By heating such a breathable member by a resistance heater or a heat medium, a liquid material in a droplet state passing therethrough is vaporized (JP2005-347598A and JP10-85581A, for example). According to this structure, since the liquid droplets are more likely to come into contact with the breathable member, the vaporization efficiency can be enhanced.

However, since the breathable member, such as a solid filler or a porous body, which has been conventionally used for vaporizing droplets of the liquid material, is heated by the heat conducted from an end of the breathable member to the whole thereof, the heat cannot be uniformly supplied to the breathable member. For example, an area of the breathable member, which is apart from the resistance heater so that the heat cannot sufficiently reach there, may become a lower temperature. In this area, the droplets may not be fully vaporized, resulting in clogging.

Further, since a lot of holes are formed in the surface of the breathable member, a passing surface area thereof is large, i.e., the breathable member is naturally, highly heat-releasable. Furthermore, the surface is exposed to the source gas and the droplets of the liquid material which have a lower temperature. Thus, the temperature of the area of the breathable member, to which the heat from the resistance heater cannot be easily transmitted, tends to be further lowered. Moreover, when the droplets of the liquid material adhere to the surface of the breathable member and are vaporized, the heat of the breathable member is drawn therefrom by vaporization heat generated at this time. In this case, the area to which the heat is difficult to be transmitted is not sufficiently replenished with a thermal energy corresponding to the vaporization heat. As a result, there is generated a temperature difference in the breathable member.

For example, in the conventional filter apparatus 10, since the breathable member 18 has a substantially cylindrical shape, the heat is conducted from the downstream end 18a toward the upstream end 18b. Thus, as a measuring point approaches the upstream end 18b from the downstream end 18a, the temperature tends to be lower. On the other hand, in the conventional filter apparatus 30, since the breathable member 34 has a discoid shape, the heat is conducted from the peripheral part thereof toward the central part thereof. Thus, as a measuring point approaches the central part from the peripheral part, the temperature tends to be lower. In a vaporizer described in JP2005-347598A, a breathable member (solid filler) is heated by a heat conducted from a resistance heater disposed outside the breathable member. Thus, as compared with an outer circumferential area of the breathable member, which is nearer to the resistance heater, the temperature of a central area thereof tends to be lower. In this case, the temperature of a certain area of the breathable member may not reach a temperature at which a liquid material can be vaporized, whereby the liquid material may not be sufficiently vaporized, resulting in clogging in this area.

On the other hand, in a vaporizer described in JP10-85581A, in order to efficiently vaporize a liquid material without clogging in a breathable member (porous body), there is provided a path passing through a part in the breathable member. By circulating a heat medium through the path, the breathable member can be heated from an inside thereof. However, this countermeasure is not sufficient in terms of prevention of clogging in the breathable member. That is, since the path through which a heat medium is circulated is disposed in only a part of the breathable member, it is still impossible to uniformly conduct a heat to the entire breathable member. Thus, a partially insufficient vaporization may still occur, and the possibility of clogging in the breathable member cannot be still eliminated.

In order to entirely transmit a heat to the breathable member, it can be considered that a lot of paths are entirely formed in the breathable member. However, when the number of paths is increased, the structure becomes complicated. In addition, since an area through which a source gas can pass is reduced by these paths, a pressure loss by the breathable member is undesirably increased.

Alternatively, in order to make uniform the temperature of the overall breathable member, it can be considered that a heat conductive path is reduced as much as possible. Specifically, in a case of the filter apparatus 10 shown in FIG. 13, it can be considered that a longitudinal dimension of the cylindrical breathable member 18 is decreased so as to reduce a distance from the downstream end 18a to the upstream end 18b. In a case of the filter apparatus 30 shown in FIG. 14, it can be considered that the diameter of the larger-diameter part 38 of the housing 32 is decreased as well as the diameter of the breathable member 34 is decreased so as to reduce a distance from the peripheral part 34a to the central part 34b. According to such a breathable member, although the uniformity in temperature of the overall breathable member can be enhanced, an area through which a source gas passes is reduced by the reduction of the heat conductive path, so that a pressure loss in the breathable member is undesirably increased. In this case, a source gas at a predetermined flow rate cannot be obtained.

### SUMMARY OF THE INVENTION

The present invention has been made in view of the above problems so as to efficiently solve the same. The object of the present invention is to provide a liquid material vaporizer capable of efficiently generating a source gas at a sufficient flow rate, and a film deposition apparatus using the same, by improving a heating efficiency (thermal conductive efficiency) of a breathable mist trap member configured to vaporize a liquid material in a droplet state, and by improving a vaporization efficiency of droplets of the liquid material.

The present invention is a liquid material vaporizer comprising a liquid-material supply part configured to make a liquid material into a droplet state and to discharge the same, and a vaporizing part configured to vaporize the liquid material in a droplet state so as to generate a source gas, the vaporizing part including: an inlet port to which the liquid material in a droplet state is introduced from the liquid-material supply part; a housing body of a bottomed tubular shape, the housing body having an opening end on a side of the inlet port; a columnar block having a flange for closing the opening end of the housing body, the columnar block being fitted in the housing body in such a manner that a gap serving as a vaporizing path is defined between the columnar block and an inside surface of the housing body; a breathable mist trap member disposed in the vaporizing path formed between the inside surface of the housing body and an outside surface of the columnar block, in such a manner that the mist trap member is in contact with the inside surface of the housing body and covers the outside surface of the columnar block; a heating part disposed to cover the housing body, the heating part being configured to heat the mist trap member through the housing body; a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state, which has been introduced from the inlet port, toward an inside surface of the mist trap member; and an outlet port disposed in a bottom part of the housing body, the outlet port being configured to deliver a source gas generated by the mist trap member that vaporizes the liquid material in a droplet state in the vaporizing path.

According to the present invention, the vaporizing path is formed in a narrow space between the housing body and the columnar block, and the mist trap member is disposed in the vaporizing path such that the mist trap member is in contact with the inside surface of the housing body. Thus, when the housing body is heated by the heating part, the heat can be transmitted from the housing body to the mist trap member via the whole contact surface(s) thereof. Therefore, since the mist trap member can be uniformly, entirely heated, when the liquid material in a droplet state is spouted from the spout of the columnar block toward the inside surface of the mist trap member, the liquid material in a droplet state can be significantly, efficiently vaporized. Moreover, since the liquid material in a droplet state is spouted from the side surface of the columnar block, which is very close to the inside surface of the mist trap member, the liquid material in a droplet state can be collided with the surface of the mist trap member at a high speed. Due to the impinging jet flow effect that is produced at this time, the heat exchange between the liquid material in a droplet state and the mist trap member is promoted, whereby the vaporization efficiency of the liquid material in a droplet state can be further improved.

In addition, it is possible to effectively prevent insufficient vaporization, which may be caused when the temperature of the mist trap member is partially lowered. Thus, clogging of the mist trap member can be prevented. Moreover, since the mist trap member has such a reduced thickness that the mist trap member can be received in the narrow space (vaporizing path) between the housing body and the columnar block, the mist trap member has a high heating efficiency (thermal conductive efficiency). Thus, even if the heat of the mist trap member is drawn as a vaporization heat when the liquid material in a droplet state comes into contact with the mist trap member so as to be vaporized, the mist trap member can be quickly replenished with a thermal energy.

For example, a thickness of the mist trap member is smaller than a width of the vaporizing path, so that a gap (clearance) in communication with the outlet port remains in the vaporizing path between the outside surface of the columnar block and the inside surface of the mist trap member.

According to this structure, after the liquid material in a droplet state has collided with the surface of the mist trap member so as to be vaporized, the liquid material in a droplet state passes through the narrow gap to which the inside surface of the mist trap member is exposed, toward the outlet port. Thus, even when not all the liquid material in a droplet state could be vaporized upon the initial collision with the mist trap member, it is highly probable that the liquid material in a droplet state again comes into contact with the mist trap member. Thus, vaporization efficiency of the liquid material in a droplet state can be further enhanced. In addition, since the gap is formed in the vaporizing path between the columnar block and the mist trap member, no space in the vaporizing part is divided by the mist trap member. Thus, even when the mist trap member is partially clogged by, e.g., insufficient vaporization of the liquid droplets of the liquid material, the generated source gas can pass through the gap so as to be delivered from the outlet port. That is, according to the present invention, since there is generated no pressure loss of the source gas, which may be caused by clogging of the mist trap member, the source gas can be supplied at a sufficient flow rate to the film deposition chamber.

Alternatively, for example, a thickness of the mist trap member is identical to a width of the vaporizing path, so that the mist trap member is disposed to fill the vaporizing path.

According to this structure, the liquid material in a droplet state can be brought into contact with the mist trap member without fail. Thus, the vaporization efficiency can be improved.

Alternatively, for example, the mist trap member is composed of an outside mist trap member in contact with the inside surface of the housing body, and an inside mist trap member in contact with the outside surface of the columnar block; and a gap in communication with the outlet port remains in the vaporizing path between an inside surface of the outside mist trap member and an outside surface of the inside mist trap member.

According to this structure, since the area of the mist trap member exposed to the gap can be increased, the liquid droplets of the liquid material passing through the gap are more likely to come into contact with the mist trap member. Thus, the vaporization efficiency can be improved.

Alternatively, for example, the spout is composed of a bottomed hole formed in the end surface of the columnar block on the side of the inlet port, and a plurality of through holes radially extending from the bottomed hole as a center toward the outside surface of the columnar block to pass therethrough.

According to this structure, since the liquid material in a droplet state is spouted from the plurality of through holes toward the mist trap member, the vaporization efficiency can be further enhanced. In addition, since the liquid material in a droplet state can be collided with the mist trap member in a circumferentially dispersed manner, a source gas at a sufficient flow rate can be generated.

In this case, for example, the respective through hoes are formed perpendicularly to an axial direction of the columnar block. According to this structure, the liquid material in a droplet state can be collided with the mist trap member at a higher speed. Thus, the impinging jet flow effect can be further improved, i.e., the vaporization efficiency can be further improved.

Alternatively, for example, the respective through holes are formed in an inclined manner with respect to an axial direction of the columnar block. According to this structure, the liquid material in a droplet state can be trapped by a larger area of the mist trap member, whereby the vaporization efficiency can be further improved.

Alternatively, for example, plural sets of the through holes, each set being composed of the through holes arranged to radially extend from the bottomed hole as a center perpendicularly to an axial direction of the columnar block, are arranged along the axial direction of the columnar block.

According to this structure, the liquid material in a. droplet state can be collided with the mist trap member at a higher speed, and the liquid material in a droplet state can be trapped by a larger area of the mist trap member. Thus, the vaporization efficiency can be further improved.

In addition, the present invention is a liquid material vaporizer to be connected to another liquid material vaporizer configured to vaporize a liquid material so as to generate a source gas, the former liquid material vaporizer comprising: an inlet port to which the source gas generated by the latter liquid material vaporizer is introduced; a housing body of a bottomed tubular shape, the housing body having an opening end on a side of the inlet port; a columnar block having a flange for closing the opening end of the housing body, the columnar block being fitted in the housing body in such a manner that a gap serving as a vaporizing path is defined between the columnar block and an inside surface of the housing body; a breathable mist trap member disposed in the vaporizing path formed between the inside surface of the housing body and an outside surface of the columnar block, in such a manner that the mist trap member is in contact with the inside surface of the housing body and covers the outside surface of the columnar block; a heating part disposed to cover the housing body, the heating part being configured to heat the mist trap member through the housing body; a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state introduced from the inlet port toward an inside surface of the mist trap member; and an outlet port disposed in a bottom part of the housing body, the outlet port being configured to deliver a source gas generated by the mist trap member that vaporizes the liquid material in a droplet state in the vaporizing path.

According to the present invention, since the material gas generated by the other liquid material vaporizer can be spouted toward the inside surface of the mist trap member that is uniformly heated as a whole, it is possible to vaporize the droplets that could not be vaporized by the other liquid material vaporizer.

In addition, the present invention is a film deposition apparatus comprising a film deposition chamber configured to perform a film deposition process to a substrate to be processed by introducing thereinto a source gas from a liquid material vaporizer, the liquid material vaporizer comprising a liquid-material supply part configured to make a liquid material into a droplet state and to discharge the same, and a vaporizing part configured to vaporize the liquid material in a droplet state so as to generate a source gas, and the vaporizing part including: an inlet port to which the liquid material in a droplet state is introduced from the liquid-material supply part; a housing body of a bottomed tubular shape, the housing body having an opening end on a side of the inlet port; a columnar block having a flange for closing the opening end of the housing body, the columnar block being fitted in the housing body in such a manner that a gap serving as a vaporizing path is defined between the columnar block and an inside surface of the housing body; a breathable mist trap member disposed in the vaporizing path formed between the inside surface of the housing body and an outside surface of the columnar block, in such a manner that the mist trap member is in contact with the inside surface of the housing body and covers the outside surface of the columnar block; a heating part disposed to cover the housing body, the heating part being configured to heat the mist trap member through the housing body; a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state, which has been introduced from the inlet port, toward an inside surface of the mist trap member; and an outlet port disposed in a bottom part of the housing body, the outlet port being configured to deliver a source gas generated by the mist trap member that vaporizes the liquid material in a droplet state in the vaporizing path.

Alternatively, the present invention is a film deposition apparatus comprising a film deposition chamber configured to perform a film deposition process to a substrate to be processed, by introducing thereinto a source gas from a liquid material vaporizer, the liquid material vaporizer comprising a first liquid material vaporizer configured to vaporize a liquid material so as to generate a source gas, and a second liquid material vaporizer connected to the first liquid material vaporizer, and the second liquid material vaporizer including: an inlet port to which the source gas generated by the first liquid material vaporizer is introduced; a housing body of a bottomed tubular shape, the housing body having an opening end on a side of the inlet port; a columnar block having a flange for closing the opening end of the housing body, the columnar block being fitted in the housing body in such a manner that a gap serving as a vaporizing path is defined between the columnar block and an inside surface of the housing body; a breathable mist trap member disposed in the vaporizing path formed between the inside surface of the housing body and an outside surface of the columnar block, in such a manner that the mist trap member is in contact with the inside surface of the housing body and covers the outside surface of the columnar block; a heating part disposed to cover the housing body, the heating part being configured to heat the mist trap member through the housing body; a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state introduced from the inlet port toward an inside surface of the mist trap member; and an outlet port disposed in a bottom part of the housing body, the outlet port being configured to deliver a source gas generated by the mist trap member that vaporizes the liquid material in a droplet state in the vaporizing path.

According to the present invention, the material gas generated by the first liquid material vaporizer can be spouted toward the inside surface of the mist trap member of the second liquid material vaporizer that is uniformly heated as a whole. Thus, it is possible to vaporize, by means of the second liquid material vaporizer, the droplets that could not be vaporized by the first liquid material vaporizer. Thus, it can be prevented that droplets of the liquid material enter a film deposition chamber together with the source gas.

### BRIEF DESCRIPTION OF THE DRAWINGS

FIG. 1 is a view showing a structural example of a film deposition apparatus in a first embodiment according to the present invention;

FIG. 2 is a longitudinal sectional view showing a structural example of a liquid material vaporizer in the first embodiment;

FIG. 3 is an exploded perspective view of components of a vaporizing part of the liquid material vaporizer of FIG. 2; FIG. 4 is an exploded perspective view of a housing body of FIG. 2;

FIG. 5 is a sectional view taken along I-I line of the housing body of FIG. 2;

FIG. 6 is a view for explaining a flow of a liquid material in a droplet state in the housing body in the first embodiment;

FIG. 7 is a view for explaining a modification of the spout formed in the columnar block;

FIG. 8 is a view for explaining another modification of the spout formed in the columnar block;

FIG. 9 is a view for explaining a modification of the mist trap member;

FIG. 10 is a view for explaining another modification of the mist trap member;

FIG. 11 is a view showing a structural example of the film deposition apparatus in a second embodiment according to the present invention;

FIG. 12 is a longitudinal sectional view showing a structural example of the liquid material vaporizer in the second embodiment;

FIG. 13 is a longitudinal sectional view showing a schematic structure of a conventional filter apparatus; and

FIG. 14 is a longitudinal sectional view showing a schematic structure of another conventional filter apparatus.

### BEST MODE FOR CARRYING OUT THE INVENTION

Preferred embodiments of the present invention will be described in detail below with reference to the accompanying drawings. In this specification and the drawings, components having substantially the same function and structure are shown by the same reference numbers, and redundant description is omitted.

### Film Deposition Apparatus in First Embodiment

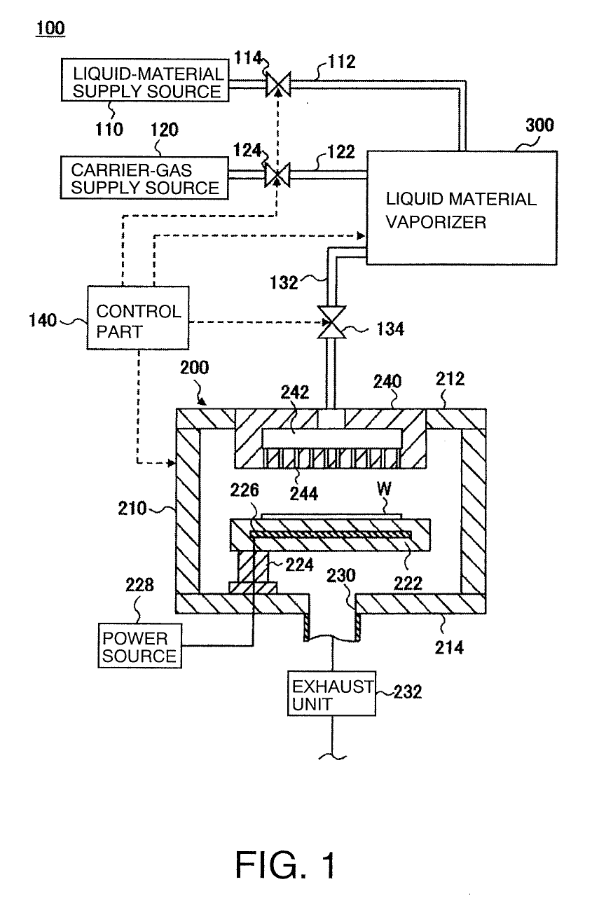

A film deposition apparatus in a first embodiment according to the present invention is firstly described with reference to the drawings. FIG. 1 is a view for explaining a schematic structural example of the film deposition apparatus in the first embodiment. The film deposition apparatus 100 shown in FIG. 1 is configured to deposit a metal oxide film on a substrate to be processed, such as a semiconductor wafer (hereinafter referred to simply as “wafer”) W, by a CVD method. For example, the film deposition apparatus 100 includes: a liquid-material supply source 110 configured to supply a liquid material containing Hf such as HTB (hafnium tertiary butoxide); a carrier-gas supply source 120 configured to supply an inert gas such as Ar as a carrier gas; a liquid material vaporizer 300 configured to vaporize the liquid material supplied from the liquid-material supply source 110 so as to generate a source gas; a film deposition chamber 200 configured to form, e.g., a HfO₂ film on a wafer W by means of the source gas generated by the liquid material vaporizer 300; and a control part 140 configured to control the respective components of the film deposition apparatus 100.

The liquid-material supply source 110 and the liquid material vaporizer 300 are connected to each other by a liquid-material supply pipe 112. The carrier-gas supply source 120 and the liquid material vaporizer 300 are connected to each other by a carrier-gas supply pipe 122. The liquid material vaporizer 300 and the film deposition chamber 200 are connected to each other by a source-gas supply pipe 132. The liquid-material supply pipe 112 is provided with a liquid-material flow-rate control valve 114. The carrier-gas supply pipe 122 is provided with a carrier-gas flow-rate control valve 124. The source-gas supply pipe 132 is provided with a source-gas flow-rate control valve 134. Opening degrees of the liquid-material flow-rate control valve 114, the carrier-gas flow-rate control valve 124, and the source-gas flow-rate control valve 134 are respectively regulated by control signals from the control part 140. The control part 140 is preferably configured to measure a flow rate of the liquid material flowing through the liquid-material supply pipe 112, a flow rate of the carrier gas flowing through the carrier-gas supply pipe 122, and a flow rate of the source gas flowing through the source-gas supply pipe 132, and to output control signals in accordance with the measurement results.

The film deposition chamber 200 includes: for example, a substantially cylindrical side wall member 210; a top wall member 212 that closes an upstream-side opening of the side wall member 210; and a bottom wall member 214 that closes a downstream-side opening of the side wall member 210. In an inside space surrounded by the side wall member 210, the top wall member 212, and the bottom wall member 214, there is disposed a susceptor 222 on which a wafer W can be horizontally placed. The side wall member 210, the top wall member 212, and the bottom wall member 214 are made of metal such as aluminum or stainless steel. The susceptor 222 is supported by a plurality of cylindrical support members 224 (although only one cylindrical support member 224 is illustrated). A heater 226 is embedded in the susceptor 222. By controlling power supplied from a power source 228 to the heater 226, a temperature of the wafer W placed on the susceptor 222 can be adjusted as desired.

An exhaust port 230 is formed in the bottom wall member 214 of the film deposition chamber 200. An exhaust unit 232 is connected to the exhaust port 230. The inside of the film deposition chamber 200 can be adjusted by the exhaust unit 232 to a predetermined vacuum degree.

A showerhead 240 is disposed on the top wall member 212 of the film deposition chamber 200. The source-gas supply pipe 132 is connected to the showerhead 240, so that the source gas generated by the liquid material vaporizer 300 is introduced into the showerhead 240 via the source-gas supply pipe 132. The showerhead 240 has an inner space 242 and a large number of gas discharge holes 244 in communication with the inner space 242. The source gas, which has been introduced into the inner space 242 of the showerhead 240 through the source-gas supply pipe 132, is discharged from the gas discharge holes 244 toward the wafer W placed on the susceptor 222.

In the film deposition apparatus 100, the source gas is supplied from the liquid material vaporizer 300 to the film deposition chamber 200 in the following manner. The liquid material is supplied to the liquid material vaporizer 300 from the liquid-material supply source 110 through the liquid-material supply pipe 112, and the carrier gas is supplied to the liquid material vaporizer 300 from the carrier-gas supply source 120 through the carrier-gas supply pipe 122. Then, a liquid-material supply part 300A on an upstream side (described below), which constitutes the liquid material vaporizer 300 together with a vaporizing part 300B on a downstream side (described below), makes the liquid material into a droplet state, and discharges the liquid material in a droplet state along with the carrier gas to the vaporizing part 300B. The vaporizing part 300B vaporizes the liquid material in a droplet state so as to generate a source gas. The source gas generated by the liquid material vaporizer 300 is supplied to the film deposition chamber 200 through the source-gas supply pipe 132. Thus, the wafer W in the film deposition chamber 200 is subjected to a desired process.

When the liquid material could not be fully vaporized in the liquid material vaporizer 300 of the film deposition apparatus 100, there is a possibility that some droplets of the liquid material may be mixed in the source gas and sent to the source-gas supply pipe 132 so as to flow into the film deposition chamber 200. The droplets of the liquid material having flowed into the film deposition chamber 200 may become particles which impair a film quality of a film to be formed on the wafer W. Alternatively, when a vaporization efficiency of the liquid material by the liquid material vaporizer 300 is deteriorated, a flow rate of the source gas to be supplied to the film deposition chamber 200 may become short. In this case, there is a possibility that a desired film deposition rate may not be achieved when an HfO₂ film is formed on the wafer W, for example.

Thus, the liquid material vaporizer 300 in this embodiment is configured to efficiently vaporize all the droplets of the liquid material so as to generate a source gas of an excellent quality, which is also sufficient in amount for a film deposition process in the film deposition chamber 200. Concrete embodiments of the liquid material vaporizer 300 are explained below.

### Structural Example of Liquid Material Vaporizer in First Embodiment

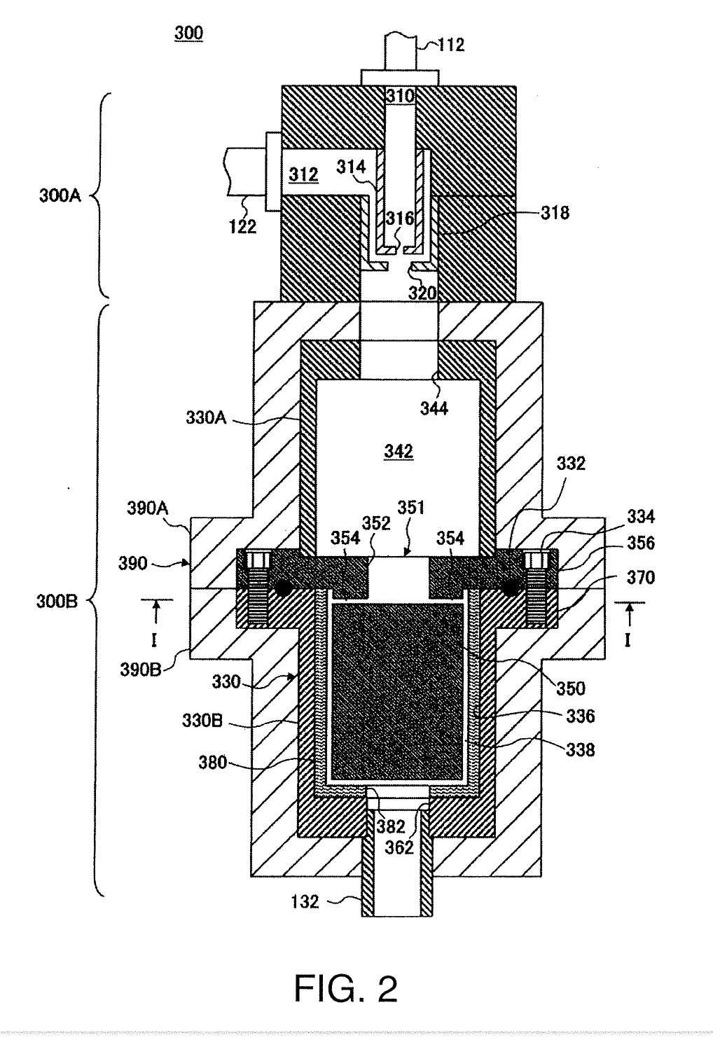

Next, a structural example of the liquid material vaporizer 300 in the first embodiment according to the present invention is described with reference to the drawings. FIG. 2 is a longitudinal sectional view showing a schematic structure of the liquid material vaporizer 300 in the first embodiment. The liquid material vaporizer 300 is mainly composed of the liquid-material supply part 300A configured to make the liquid material into a droplet state and to supply the liquid material in a droplet state to a downstream member, and the vaporizing part 300B configured to vaporize the liquid material in a droplet state supplied from the liquid-material supply part 300A.

A structural example of the liquid-material supply part 300A is described in the first place. The liquid-material supply part 300A is provided with a liquid material path 310 vertically extending inward from an upstream surface, and a carrier gas path 312 horizontally extending inward from a side surface. The liquid-material supply pipe 112 is connected to one end of the liquid material path 310, and the carrier-gas supply pipe 122 is connected to one end of the carrier gas path 312.

Connected to the other end of the liquid material path 310 is a discharge nozzle 314 configured to make the liquid material into a droplet state and to discharge the same. The discharge nozzle 314 is narrowed to a distal end thereof, for example (detailed illustration of this structure is omitted in FIG. 2). The discharge nozzle 314 is arranged such that a discharge opening 316 in the distal end thereof is directed toward an inside of the vaporizing part 300B.

A diameter of the discharge opening 316 of the discharge nozzle 314 is determined depending on a target size of a droplet of the liquid material to be supplied into the vaporizing part 300B. In order to unfailingly vaporize the liquid material in a droplet state in the vaporizing part 300B, the droplets of a smaller size are advantageous. Thus, the diameter of the discharge opening 316 is preferably smaller. However, when the size of the droplets is too small, there is a possibility that a flow rate of the source gas obtained by vaporizing the droplets may become short. In consideration of these respects, the diameter of the discharge opening 316 is preferably determined.

As a material for constituting the discharge nozzle 314, a synthetic resin such as a polyimide resin, or a metal such as stainless steel or titanium, which is resistant to an organic solvent, is preferred. When the discharge nozzle 314 is made of a synthetic resin, a heat will not be conducted from around to the liquid material before being discharged. In particular, when a polyimide resin is used, residues (deposits) of the liquid material are unlikely to adhere to the discharge nozzle 314, whereby clogging of the nozzle can be prevented.

Inside the liquid-material supply part 300A, a carrier-gas discharge part 318 is arranged to surround the distal end of the discharge nozzle 314. The carrier-gas discharge part 318 is connected to the other end of the carrier gas path 312, and extends vertically, with the discharge nozzle 314 being accommodated therein. Thus, the carrier-gas discharge part 318 is configured to jet the carrier gas from the carrier gas path 312, together with the liquid material, toward the inside of the vaporizing part 300B.

More specifically, the carrier-gas discharge part 318 is formed to have a cup-like shape (hollow shape) surrounding the distal end of the discharge nozzle 314. A carrier-gas discharge opening 320 is formed in a bottom part of the carrier-gas discharge part 318. The carrier-gas discharge opening 320 is formed near to the discharge opening 316 in the distal end of the discharge nozzle 314, so as to surround the discharge opening 316. Thus, the carrier gas can be jetted from around the discharge opening 316. Therefore, the droplets of the liquid material discharged from the discharge opening 316 can be allowed to fly toward the vaporizing part 300B without fail, so that the droplets of the liquid material can be unfailingly guided up to a mist trap member, which is described below, provided in the vaporizing part 300B.

Next, a structural example of the vaporizing part 300B is described. The vaporizing part 300B includes a housing 330 having an introduction part 330A and a housing body 330B. The introduction part 330A has an inlet port 344 to which a gas containing the liquid material in a droplet state is introduced from the liquid-material supply part 300A. The housing body 330B has a vaporizing path 336 configured to vaporize the liquid material in a droplet state having been introduced to the introduction part 330A, and an outlet port 362 in communication with the vaporizing path 336.

A columnar block 350 is fitted (loosely fitted) in the housing body 330B with a gap therebetween. Thus, the substantially cylindrical vaporizing path 336 is defined between an outside surface of the columnar block 350 and an inside surface of the housing body 330B. Disposed in the vaporizing path 336 is the mist trap member 380 configured to capture (trap) and vaporize the droplets of the liquid material. The mist trap member 380 is heated by a heating part 390 that is arranged to surround the housing 330. The columnar block 350 is provided with a spout 351 from which the liquid material in a droplet state, which has been introduced to the introduction part 330A, is spouted toward an inside surface of the mist trap member 380.

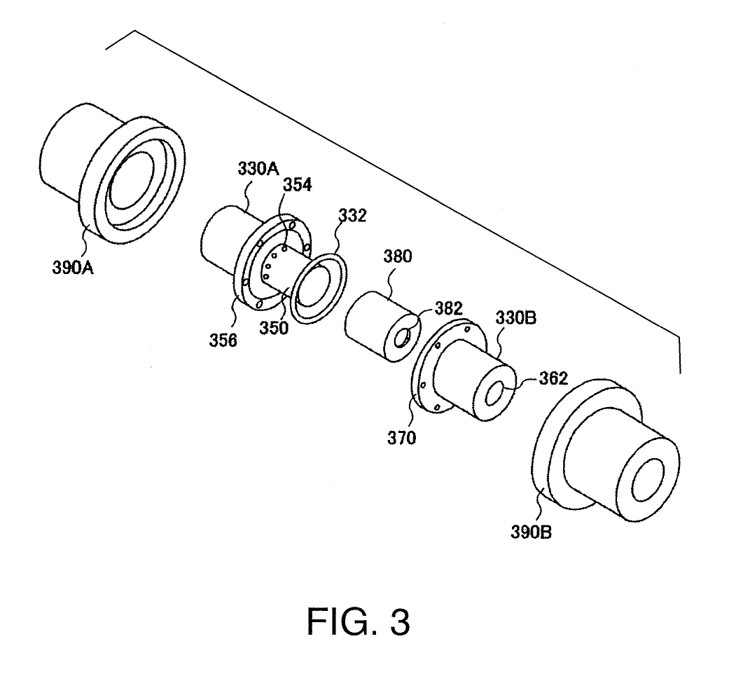

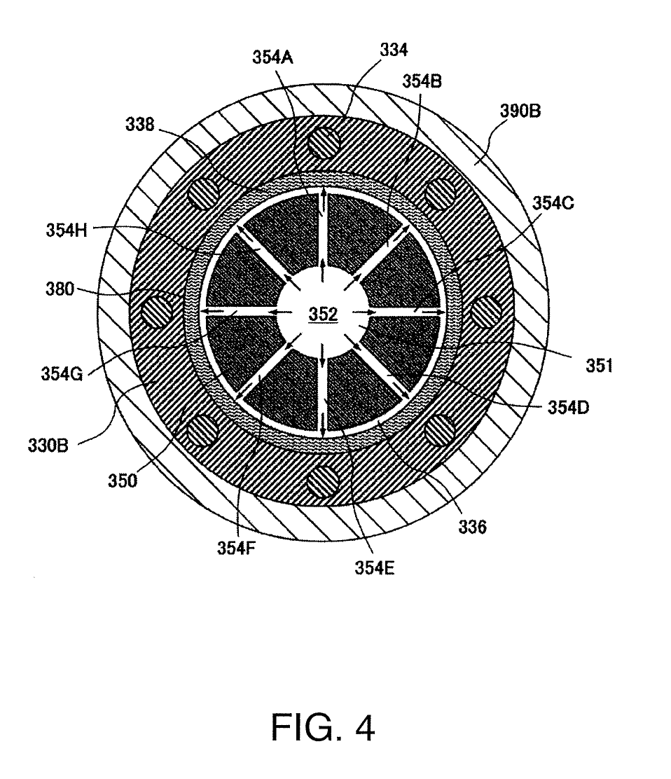

The structures of the respective components of the vaporizing part 300B are described in more detail with reference to the drawings. FIG. 3 is an exploded perspective view of the components of the vaporizing part 300B. FIG. 4 is a sectional view taken along the line I-I of FIG. 2. The arrows in FIG. 4 show flows of the liquid material in a droplet state.

As shown in FIGS. 2 and 3, for example, the housing body 330B has a bottomed tubular (herein cylindrical) shape, with an opening end being provided on the upstream side (on the side of the inlet port 344). A flange part 370 is disposed on the upstream opening end of the housing body 330B, and the outlet port 362 is formed in the downstream bottom thereof. The outlet port 362 is connected to the source-gas supply pipe 132.

The columnar block 350 is loosely fitted in the housing body 330B such that a substantially cylindrical narrow space (gap) is defined between the columnar block 350 and the inside surface of the housing body 330B. The narrow space between the outside surface of the columnar block 350 and the inside surface of the housing body 330B constitutes the vaporizing path 336 for vaporizing the droplets of the liquid material.

A flange part 356 is disposed on an upstream end of the columnar block 350. The flange part 356 of the columnar block 350 is joined to the flange part 370 of the housing body 330B by fastening members 334 such as bolts. Thus, the upstream opening end of the housing body 330B is closed.

It is preferable to interpose a sealing member 332, such as a metal O-ring, between the joined surfaces of the flange parts 356 and 370, so as to improve an air-tightness inside the housing body 330B.

The mist trap member 380 is disposed in the vaporizing path 336 formed between the outside surface of the columnar block 35 and the inside surface of the housing 330. The mist trap member 380 is formed of a breathable member that captures and vaporizes the droplets of the liquid material without allowing the same to pass therethrough, but allows a source gas thus generated to pass therethrough. As a material constituting the breathable member, it is preferable to use a material to which a heat from the housing body 330B, which is heated by the heating part 390, is easily transmitted. As such a material, a metal such as stainless steel having a porous structure or a mesh structure can be taken by way of example. Alternatively, ceramics or plastics having a high thermal conductivity can be used.

The mist trap member 380 has a thin cup-like shape (cylindrical shape), with an upstream end thereof being opened and a downstream end thereof being closed, for example. Formed in the downstream end of the mist trap member 380 is a hole 382 that is in communication with and integral with the outlet port 362. In order that a heat from the housing body 330B, which is heated by the heating part 390, is conducted entirely to the mist trap member 380, the mist trap member 380 is arranged so as to be in close contact with the inside surface of the housing body 330B and to cover the columnar block 350. In this embodiment, a thickness of the mist trap member 380 is smaller than a width of the vaporizing path 336 between the columnar block 350 and the housing body 330B. Thus, there remains a gap (clearance) 338 in communication with the outlet port 362, between the outside surface of the columnar block 350 and the inside surface of the mist trap member 380.

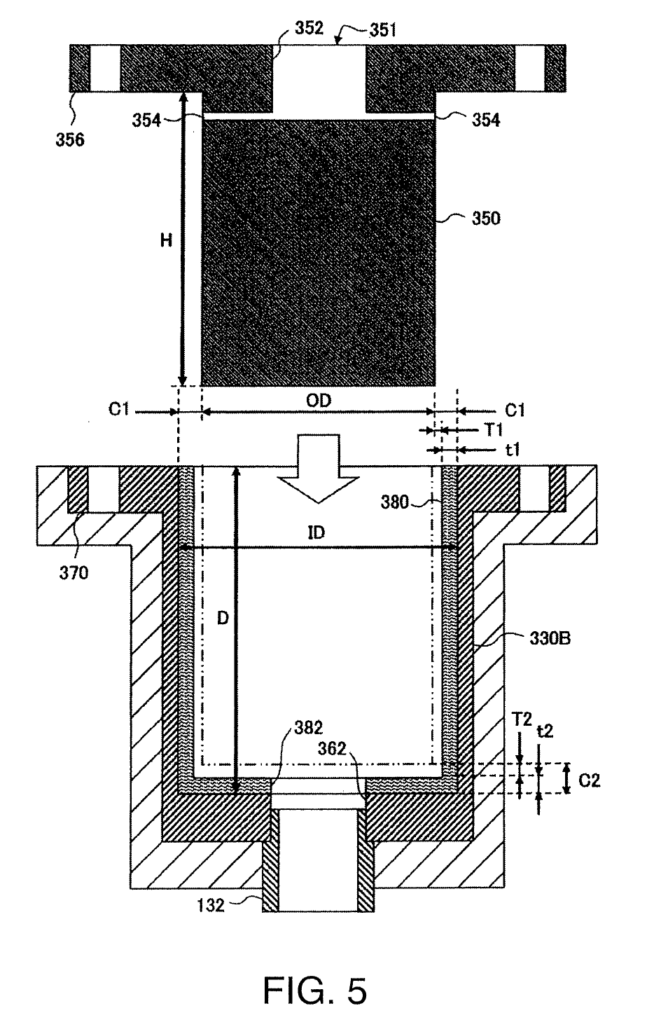

The vaporizing path 336 formed inside the housing body 330B and the gap 338 formed in the vaporizing path 336 are described in more detail with reference to the drawings. FIG. 5 is a schematic view when the columnar block 350 is inserted into the housing body 330B in which the mist trap member 380 has been fitted.

As shown in FIG. 5, the columnar block 350 is formed such that a height H from a lower end surface of the flange part 356 to a bottom surface of the columnar block 350 is smaller than an inside depth D of the housing body 330B, and that an outer diameter OD of the columnar block 350 is smaller than an inner diameter ID of the housing body 330B. Thus, when the columnar block 350 is inserted to the inside of the housing body 330B, there are defined a cylindrical narrow space C1 (whose width equals to (ID-OD)/2) between an outer circumferential surface of the columnar block 350 and an inner circumferential surface of the housing body 330B, and a discoid narrow space C2 (whose height equals to D-H) between a bottom surface of the columnar block 350 and an inner bottom surface of the housing body 330B. These narrow spaces C1 and C2 constitute the vaporizing path 336.

At this time, when the mist trap member 380 is arranged in the vaporizing path 336, with thicknesses (t1, t2) of the mist trap member 380 being smaller than the widths (C1, C2) of the vaporizing path 336, as shown in FIG. 5, there are defined a cylindrical gap T1 (whose width equals to (ID-OD)/2-t1) between the outer circumferential surface of the columnar block 350 and an inner circumferential surface of the mist trap member 380, and a discoid gap T2 (whose height equals to (D-H)-t2) between the bottom surface of the columnar block 350 and an inner bottom surface of the mist trap member 380. These gaps T1 and T2 constitute the gap (clearance) 338 in communication with the outlet port 362.

The introduction part 330A has a bottomed tubular (herein cylindrical) shape, with an opening end being provided on the downstream side. The inlet port 344 for the liquid material in a droplet state is formed in an upstream ceiling part of the introduction part 330A, and a downstream opening end of the introduction part 330A is connected to an upstream end surface of the columnar block 350 so as to be closed. Thus, an introduction space 342 of the introduction part 330A communicates the inlet port 344 with the spout 351 formed inside the columnar block 350, and serves as an introduction path for guiding the liquid material in a droplet state, which has entered from the inlet port 344, to the spout 351.

The spout 351 is formed to pass through the columnar block 350 from the upstream end surface thereof to a side surface thereof. Thus, the liquid material in a droplet state having been introduced form the inlet port 344 can be spouted toward the inside surface of the mist trap member 380 in the vaporizing path 336. As shown in FIGS. 2 and 4, for example, the spout 351 includes: a bottomed hole 352, which is formed in a central part of the upstream end surface facing the inlet port 344 and extends in an axial direction of the columnar block 350; and a plurality of through holes 354, which extend radially from the bottomed hole 352 as a center toward the outside surface of the columnar block 350 to pass therethrough. FIGS. 2 and 4 show the concrete example in which the through holes 354 are formed perpendicularly to the axial direction of the columnar block 350.

Both the introduction part 330A and the housing body 330B are made of a highly conductive material, which can easily transmit a heat from the heating part 390. For example, metal such as aluminum or stainless steel can be used as the highly conductive material.

The heating part 390 is arranged to cover the outsides of the aforementioned introduction part 330A, of the columnar block 350, and of the housing body 330B. Specifically, the heating part 390 includes a bottomed tubular (herein cylindrical) upstream heating member 390A having an opening end on the downstream side, and a bottomed tubular (herein cylindrical) downstream heating member 390B having an opening end that is joined to the opening end of the upstream heating member 390A. For example, a resistance heater, not shown, is embedded in the entire upstream heating member 390A and the entire downstream heating member 390B. The resistance heater is configured to be heated by means of power from a heater power source, not shown.

The entire housing 330 is heated by this heating part 390, and the mist trap member 380 is heated through the housing 330. Thus, the mist trap member 380 can be uniformly, entirely heated. By heating the entire housing 330, the heat is transmitted to the columnar block 350. Since the mist trap member 380 is heated also by the columnar block 350, a heating efficiency can be enhanced.

The heater embedded in the heating part 390 is not limited to the above resistance heater, but may be a radiant heater, such as a carbon heater, a halogen heater, or a nichrome heater, which heats the housing 330 and the mist trap member 380 by radiant heat. In addition, the heating part 390 herein is arranged to cover the outside of the housing 330. However, not limited thereto, the heating part 390 may be embedded in the housing 330, for example.

(Operation of Film Deposition Apparatus)

Next, an operation of the film deposition apparatus 100 in this embodiment is described. The film deposition apparatus 100 is operated, with the respective components thereof being controlled by the control part 140. When a source gas is generated by the liquid material vaporizer 300, the whole housing 330 is previously heated to a predetermined set temperature, by the heating part 390 of the liquid material vaporizer 300. When the housing 330 is heated, the heat is conducted to the mist trap member 380 through the housing body 330B (and the columnar block 350), so that the mist trap member 380 is heated. At this time, the mist trap member 380 has a temperature (e.g., 100 to 300° C.) that is higher than the vaporization temperature of the liquid material, for example. The mist trap member 380 is heated to such a temperature and is held thereat.

The mist trap member 380 has the reduced thickness, and is in surface-contact with the inside surface of the housing body 330B. Thus, the heat can be easily conducted to the overall mist trap member 380. Namely, the whole mist trap member 380 can be uniformly heated for a short period of time. In addition, even when the liquid material in a droplet state having a lower temperature comes into contact with the mist trap member 380 so that the temperature of the mist trap member 380 is lowered, the temperature of the mist trap member 380 can be instantaneously recovered (temperature recovery). Thus, the temperature of the mist trap member 380 can be constantly maintained.

Following thereto, the opening degree of the liquid-material flow-rate control valve 114 is regulated such that the liquid material is supplied at a predetermined flow rate from the liquid-material supply source 110 to the liquid material vaporizer 300 through the liquid-material supply pipe 112. Simultaneously, the opening degree of the carrier-gas flow-rate control valve 124 is regulated such that the carrier gas is supplied at a predetermined flow rate from the carrier-gas supply source 120 to the liquid material vaporizer 300 through the carrier-gas supply pipe 122.

The liquid material supplied to the liquid material vaporizer 300 passes through the liquid material path 310 to be discharged from the discharge opening 316 of the discharge nozzle 314 in a droplet state. The carrier gas, which is supplied along with the liquid material to the liquid material vaporizer 300, passes through the carrier gas path 312 to be discharged from the carrier-gas discharge opening 320 of the carrier-gas discharge part 318 toward the vaporizing part 300B.

Since the carrier gas to be discharged passes a space in the vicinity of the discharge opening 316 of the discharge nozzle 314, the droplets of the liquid material, which are continuously discharged from the discharge opening 316, can be supplied (guided) to the inlet port 344 of the vaporizing part 300B, with the aid of the flow of the carrier gas.

The droplets of the liquid material supplied from the inlet port 344 are supplied into the housing body 330B through the introduction space 342 of the introduction part 330A. As described above, the atmosphere in the introduction space 342 has been heated by the heating part 390 beforehand. Thus, some of the droplets of the liquid material can be vaporized also in this introduction space 342.

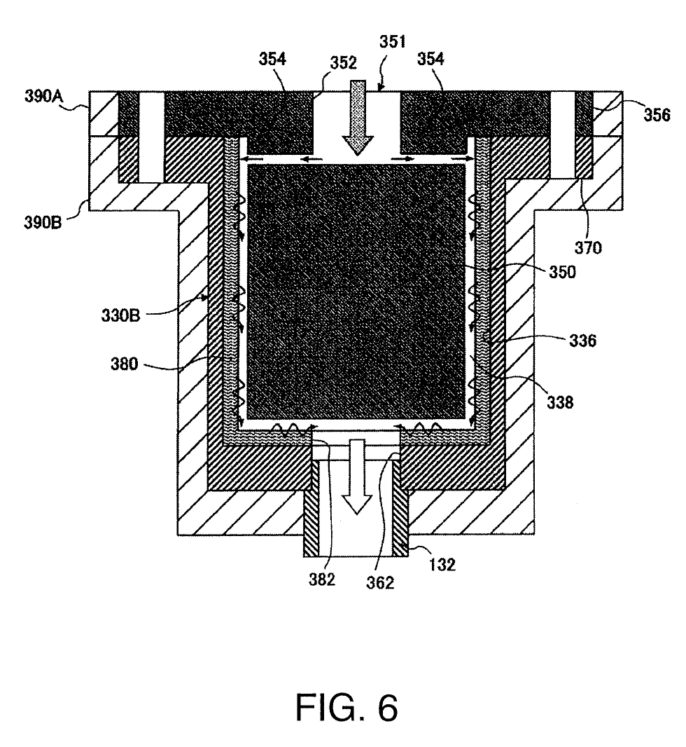

A flow of the liquid material in a droplet state in the housing body 330B is described with reference to the drawings. FIG. 6 is a longitudinal sectional view of the columnar block 350 and the housing body 330B in which the mist trap member 380 is fitted, for explaining the flow of the liquid material in a droplet state.

As shown in FIGS. 4 and 6, the droplets of the liquid material from the introduction part 330A are guided to the spout 351 of the columnar block 350, and are spouted from the spout 351 onto the inside surface of the mist trap member 380. Namely, the droplets of the liquid material flow into the bottomed hole 352, and are spouted from the plurality of through holes 354 (354A to 354H as shown in FIG. 4) so as to be sprayed onto the mist trap member 380. At this time, as shown in FIG. 4, for example, when a hole diameter of each through hole 354 is smaller than a hole diameter of the bottomed hole 352, a flow speed of the droplets of the liquid material in the respective through holes 354 can be increased. Thus, the liquid droplets of the liquid material can be sprayed toward the mist trap member 380 at a higher speed.

The respective through holes 354 shown in FIG. 6 are formed perpendicularly to the axial direction of the columnar block 350. Thus, the droplets of the liquid material which are spouted from the respective through holes 354 can be substantially perpendicularly collided with the inside surface of the mist trap member 380, while maintaining the fast speed thereof.

At this time, since the entire mist trap member 380 has been uniformly heated beforehand by the heating part 390 (downstream heating member 390B), almost all the liquid material in a droplet state colliding with the mist trap member 380 is vaporized in a moment. In addition, since the droplets of the liquid material are spouted toward the inside surface of the mist trap member 380 at a fast speed, the collision speed is high, whereby a heat exchange between the liquid material in a droplet state and the mist trap member 380 can be more efficiently performed by a collision jet effect. Thus, as compared with the conventional technique, a significantly improved vaporization efficiency can be provided.

In addition, since the respective through holes 354 are radially formed from the bottomed hole 352 of the columnar block 350 toward the outside surface thereof at equal angles, the liquid material in a droplet state having flowed into the bottomed hole 352 are equally dispersed in the circumferential direction. Thus, the liquid material in a droplet state is not partially collided with the mist trap member 380, but uniformly collided therewith in the circumferential direction. Therefore, the vaporization efficiency of the liquid material in a droplet state can be further enhanced.

As described above, the liquid droplets of the liquid material spouted from the spout 351 of the columnar block 350 collide with the inside surface of the mist trap member 380 at the high speed to be vaporized, so that a source gas is generated. The source gas passes through the vaporizing path 336 (herein, mainly through the gap 338 between the columnar block 350 and the mist trap member 380) so as to be delivered to the source-gas supply pipe 132 from the outlet port 362.

Although almost all the droplets of the liquid material are vaporized upon the initial collision with the mist trap member 380, some may not be vaporized. The droplets of the liquid material that could not be vaporized may flow downstream, together with the source gas, through the gap 338 to which the inside surface of the mist trap member 380 is exposed. For this while, the droplets of the liquid material that could not be vaporized may come into contact with the inside surface of the mist trap member 380 or enter the same, so that the droplets of the liquid material that could not be vaporized may be heated and vaporized.

In particular, since the gap 338 in this embodiment is extremely narrow, it is highly possible that the droplets of the liquid material that could not be vaporized come into contact with the inside surface of the mist trap member 380. Moreover, the contact is likely to occur many times. In addition, the mist trap member 380 in this embodiment has a high surface degree of roughness. Further, even when the vaporization heat is drawn by the droplets of the liquid material, the temperature of the mist trap member 380 can be immediately recovered. Thus, when the droplets of the liquid material flowing downward through the gap 338 come into contact with the mist trap member 380, it can be expected that the mist trap member 380 can trap the droplets of the liquid material and efficiently vaporize the same.

That is to say, when the liquid material in a droplet state flowing through the gap 338 comes into contact with the inside surface of the mist trap member 380, the liquid material in a droplet state is once trapped by the inside surface of the mist trap member 380 which has a high surface degree of roughness. At this time, as described above, since the temperature of the inside surface of the mist trap member 380 has been heated to a temperature sufficient for vaporizing the liquid material, when the liquid material in a droplet state is trapped, the liquid material in a droplet state is vaporized instantaneously. Thus, even when the liquid material in a droplet state cannot be fully vaporized in the initial trapping, the amount of the liquid material in a droplet state that has not yet been vaporized is gradually decreased by the repeated contact with the mist trap member 380 in the course of flowing through the gap 338.

Although nearly impossible, suppose that there exist the droplets of the liquid material which flow straight in the gap 338 in parallel with the side surface of the columnar block 350. In this case, however, as shown in FIG. 6, since the gap 338 is bent at the bottom part of the mist trap member 380, such droplets of the liquid material collide with the bottom part of the mist trap member 380 so as to be vaporized.

As described above, almost all the droplets of the liquid material collide with the inside surface of the mist trap member 380 so as to be vaporized. Even if some droplets could not be vaporized, such droplets can be fully vaporized, while the droplets flow through the gap 338 or inside the mist trap member 380 together with the carrier gas. Thus, all the droplets are vaporized to become a source gas, which is then delivered to the source-gas supply pipe 132 via the outlet port 362.

The source gas having been delivered to the source-gas supply pipe 132 is supplied to the film deposition chamber 200. The source gas is then introduced into the inner space 242 of the showerhead 240, and is discharged from the gas discharge holes 244 toward the wafer W placed on the susceptor 222. Thus, a predetermined film such as a HfO₂ film is formed on the wafer W. A flow rate of the source gas to be introduced into the film deposition chamber 200 can be regulated by controlling the opening degree of the source-gas flow-rate control valve 134 provided in the source-gas supply pipe 132.

As described above, in the liquid material vaporizer 300 in the first embodiment, the vaporizing path 336 is formed in the narrow space between the housing body 330B and the columnar block 350, and the mist trap member 380 is disposed in the vaporizing path 336 such that the mist trap member 380 is in contact with the inside surface of the housing body 330B. Thus, according to the liquid material vaporizer 300 in the first embodiment, when the housing body 330B is heated by the heating part 390, the heat can be transmitted from the housing body 330B to the mist trap member 380 via the whole contact surfaces thereof.

Therefore, since the mist trap member 380 can be uniformly, entirely heated, when the liquid material in a droplet state is spouted from the spout of the columnar block 350 toward the inside surface of the mist trap member 380, the liquid material in a droplet state can be significantly, efficiently vaporized. Moreover, since the liquid material in a droplet state is spouted from the side surface of the columnar block 350, which is very close to the inside surface of the mist trap member 380, the liquid material in a droplet state can be jetted and collided with the surface of the mist trap member 380 at a high speed. Due to the impinging jet flow effect that is produced at this time, the heat exchange between the liquid material in a droplet state and the mist trap member 380 is promoted, whereby the vaporization efficiency of the liquid material in a droplet state can be further improved.

In addition, it is possible to effectively prevent insufficient vaporization, which may be caused when the temperature of the mist trap member 380 is partially lowered. Thus, clogging of the mist trap member 380 can be prevented. As a result, a lifetime of the mist trap member 380 can be prolonged, and a maintenance cycle of the liquid material vaporizer 300 can be elongated. Further, only the mist trap member 380 can be removed for replacement, and a time required for the maintenance operation can be reduced. Thus, a throughput in the film deposition apparatus 100 can be enhanced.

Moreover, since the mist trap member 380 has such a reduced thickness that the mist trap member 380 can be received in the narrow space (vaporizing path 336) between the inside surface of the housing body 330B and the outside surface of the columnar block 350, the mist trap member 380 has a high heating efficiency (thermal conductive efficiency). Thus, even if the heat of the mist trap member 380 is drawn as a vaporization heat when the liquid material in a droplet state comes into contact with the mist trap member 380 so as to be vaporized, the mist trap member 380 can be quickly replenished with a thermal energy.

In addition, the inside surface of the mist trap member 380 is exposed to the gap 338 defined in the vaporizing path 336. Further, since the inside surface is formed of a rough surface and is heated to a high temperature, the liquid droplets of the liquid material passing through the gap 338 can be trapped on the inside surface of the mist trap member 380 so as to be vaporized, without Leidenfrost phenomenon. Thus, a source gas of high quality, which is free of not-vaporized component, can be supplied to the film deposition chamber 200.

Further, in the vaporizing part 300B shown in FIG. 2, since the gap 338 in communication with the outlet port 362 is formed in the vaporizing path 336 in which the mist trap member 380 is disposed, no space in the vaporizing part 300B is divided by the mist trap member 380. Thus, even when the mist trap member 380 is partially clogged by, e.g., insufficient vaporization of the liquid droplets of the liquid material, the generated source gas can pass through the gap 338 so as to be delivered from the outlet port 362. That is, since there is generated no pressure loss of the source gas, which may be caused by clogging of the mist trap member 380, the source gas can be supplied at a sufficient flow rate to the film deposition chamber 200.

In the first embodiment, each of the housing 330, the mist trap member 380, and the heating part 390 has a cylindrical shape, which is by way of example. Not limited thereto, each of the housing 330, the mist trap member 380, and the heating part 390 may have a rectangular parallelepiped shape or another tubular shape, instead of the cylindrical shape. In such a case, a prismatic block in place of the columnar block 350 is preferably provided in the housing 330.

In addition, although the vaporizing part 300B in the first embodiment is composed of the introduction part 330A and the housing body 3306, the introduction part 330A may be omitted. To be specific, for example, a liquid-material supply part 300A may be directly connected to the upstream end surface of the columnar block 350, so that the liquid droplets of the liquid material discharged from the discharge opening 316 are introduced to the bottomed hole 352 of the columnar block 350. The bottomed hole 352 in this structure also serves as an inlet port of the liquid material in a droplet state.

In addition, in the vaporizing part 300B shown in FIG. 2, although the spout 351 formed inside the columnar block 350 is composed of the bottomed hole 352 formed in the upstream end surface, and of the plurality of through holes 354 radially extending from the bottomed hole 352 as a center toward the outside surface of the columnar block 350 perpendicularly to the axial direction of the columnar block 350, the present invention is not limited thereto.

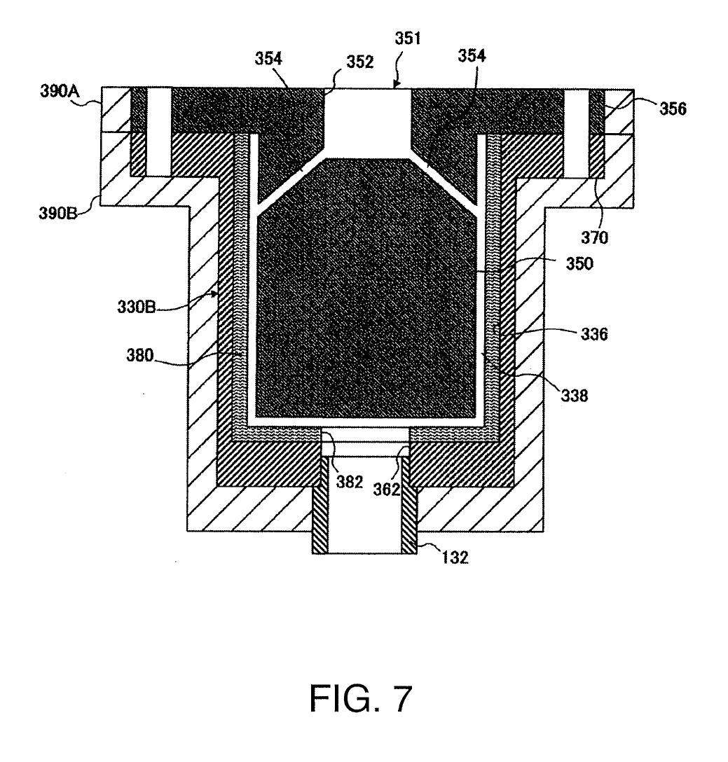

For example, as shown in FIG. 7, the respective through holes 354 may be formed in an inclined manner with respect to the axial direction of the columnar block 350. According to this structure, the liquid droplets of the liquid material spouted from the respective through holes 354 can be obliquely collided with the inside surface of the mist trap member 380. In this case, the liquid droplets of the liquid material can be trapped by a larger area of the inside surface of the mist trap member 380. Thus, the vaporization efficiency of the liquid droplets of the liquid material can be further enhanced.

In addition, since the respective through holes 354 shown in FIG. 7 are obliquely formed, the liquid material in a droplet state flowing from the upstream side to the bottomed hole 352 can be more smoothly guided to the respective through holes 354. As a result, the liquid material in a droplet state can be efficiently vaporized for a short period of time, so that a larger amount of source gas can be generated.

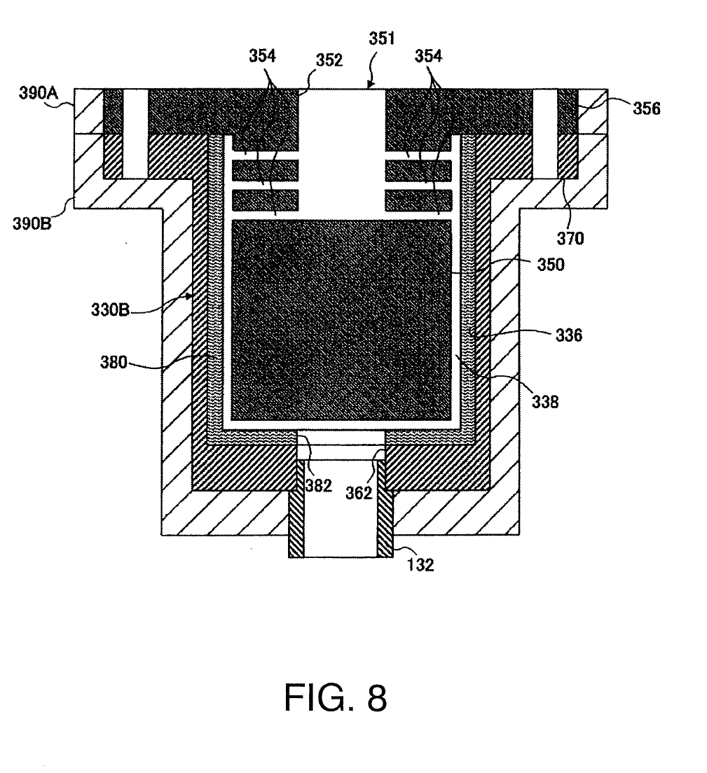

In the columnar block 350 shown in FIG. 4, although the eight through holes 354 (354A to 354H) are illustrated by way of example, the number of the through holes 354 is not limited thereto. For example, in order to generate a larger amount of source gas, a larger number of the through holes 354 may be formed. When the number of the through holes 354 is increased, new through hole(s) 354 may be added in the circumferential direction of the columnar block 350. Alternatively, as shown in FIG. 8, plural sets (e.g., three sets) of the through holes 354, each set being composed of the plurality of through holes 354 (herein eight through holes 354) arranged to radially extend from the bottomed hole 352 as a center perpendicularly to the axial direction of the columnar block 350, may be arranged along the axial direction of the columnar block 350.

According to this structure, the liquid material in a droplet state spouted from the respective through holes 354 can be trapped by a larger area of the inside surface of the mist trap member 380. Although the number of the through holes 354 is increased, the increasing manner is to add the set of the through holes 354 at each position displaced in the axial direction of the columnar block 350. Thus, the liquid material in a droplet state spouted from the respective through holes 354 can be trapped by separate areas, which are not overlapped with each other, of the inside surface of the mist trap member 380. Thus, a source gas of a sufficient flow rate can be generated, without decreasing the vaporization efficiency.

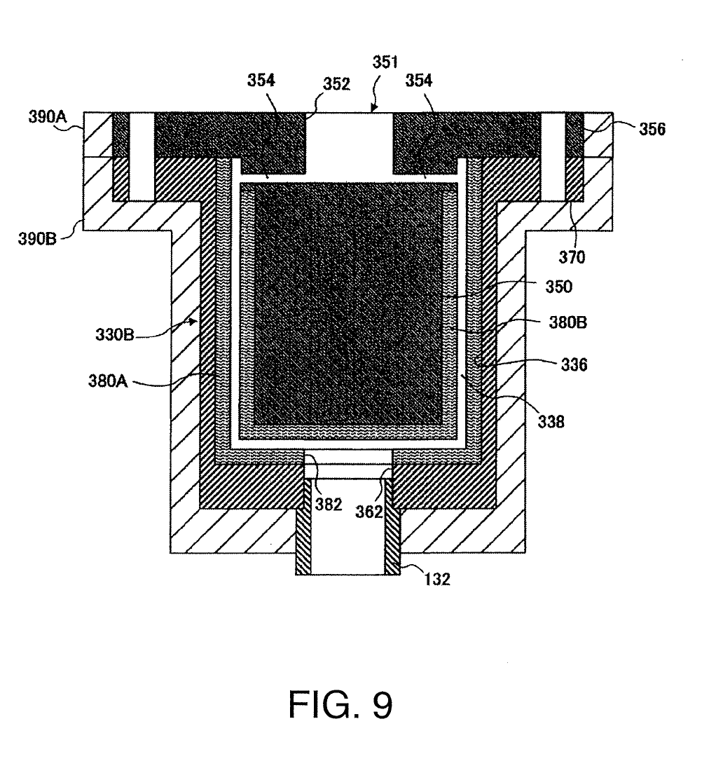

In addition, in the vaporizing part 300B shown in FIG. 2, although the one mist trap member 380 is disposed between the columnar block 350 and the housing body 330B, the present invention is not limited thereto. For example, as shown in FIG. 9, the mist trap member 380 may be separately structured as an outside mist trap member 380A, which is in close contact with the inside surface of the housing body 330B, and an inside mist trap member 380B, which is in close contact with the outside surface of the columnar block 350. In this case, the gap 338 in the vaporizing path 336 in communication with the outlet port 362 is formed between an inside surface of the outside mist trap member 380A and an outside surface of the inside mist trap member 380B. Both the outside mist trap member 380A and the inside mist trap member 380B are preferably formed of the aforementioned breathable member.

Also in this case, as described above, the columnar block 350 is made of a material having a high thermal conductivity. Thus, since not only the housing body 330B but also the columnar block 350 is heated by the heating part 390, the heat is transmitted from the housing body 330B to the outside mist trap member 380A so as to be heated, and the heat is transmitted from the columnar block 350 to the inside mist trap member 380B so as to be heated. Similarly to the outside mist trap member 380A, since the inside mist trap member 380B has a thin cup-like shape, the whole inside mist trap member 380B can be uniformly heated.

According to this structure, the inside surface of the outside mist trap member 380A, which is heated to a high temperature, and the outside surface of the inside mist trap member 380B, which is also heated to a high temperature, are both exposed to the gap 338. Thus, the liquid material in a droplet state passing through the gap 338 is trapped by one of the surfaces and vaporized. Since the area of the mist trap member 380 exposed to the gap 338 is remarkably increased, the probability of the droplets of the liquid material passing through the gap 338 being trapped by the mist trap member 380 can be increased, whereby the vaporization efficiency of the liquid material can be improved.

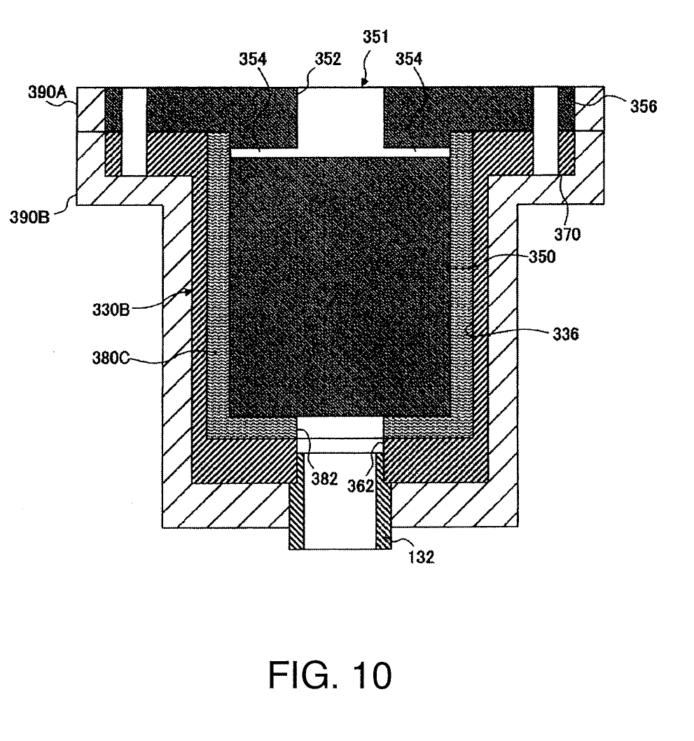

In addition, in the vaporizing part 300B shown in FIG. 2, although the thickness of the mist trap member 380 is smaller than the width of the vaporizing path 336 between the outside surface of the columnar block 350 and the inside surface of the housing body 330B, so as to define the gap 338 in the vaporizing path 336, the present invention is not limited thereto. For example, as shown in FIG. 10, there may be used a mist trap member 380C whose thickness is identical to the width of the vaporizing path 336 between the outside surface of the columnar block 350 and the inside surface of the housing body 330B. Namely, the vaporizing path 336 between the columnar block 350 and the housing body 330B may be filled with the mist trap member 380C.

When the vaporizing path 336 is filled with the mist trap member 380C, the liquid material in a droplet state spouted from the respective through holes 354 is trapped by the mist trap member 380 and vaporized without fail. The thus generated source gas passes through the inside of the mist trap member 380, which serves as a path 336, so as to be delivered from the outlet port 362.

Since the outside surface and the inside surface of the mist trap member 380C are respectively in close contact with the outside surface of the columnar block 350 and the inside surface of the housing body 330B, a heat is conducted to both the outside surface and the inside surface of the mist trap member 380C, whereby the mist trap member 380C can be uniformly heated to a high temperature as a whole. Thus, the liquid material in a droplet state passing through the inside of the mist trap member 380C can be more reliably vaporized.

When the vaporizing path 336 is filled with the mist trap member 380C, there exists no gap 338. Thus, in order that a conductance of the flow of the source gas is not lowered, as a breathable member constituting the mist trap member 380C, a breathable member of a coarse texture is preferably used.

### Film Deposition Apparatus in Second Embodiment

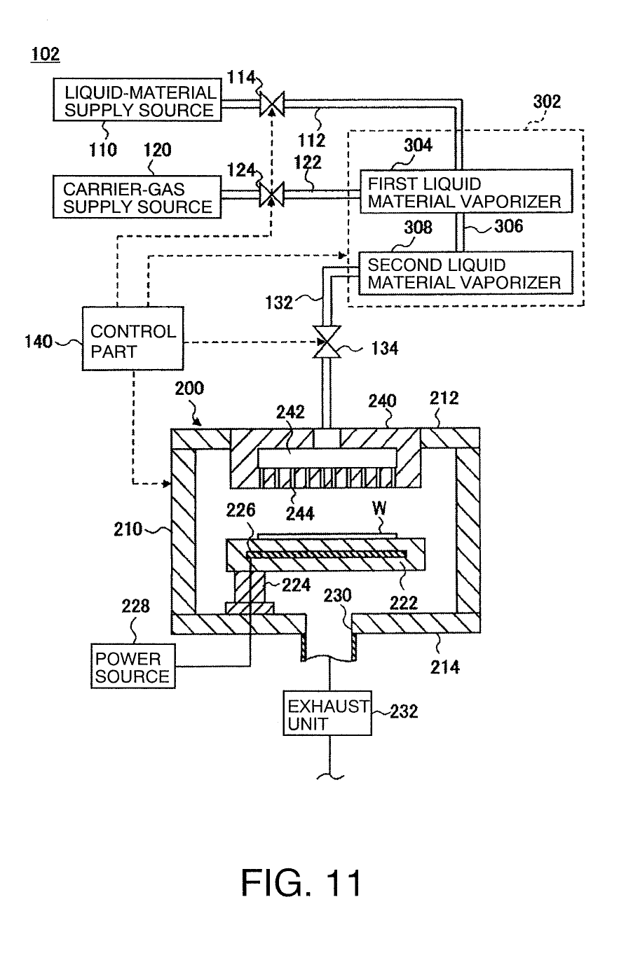

Next, the film deposition apparatus in a second embodiment according to the present invention is described with reference to the drawings. FIG. 11 is a view for explaining a schematic structural example of the film deposition apparatus 102 in the second embodiment. In the film deposition apparatus 102 shown in FIG. 11, the liquid material vaporizer 300 shown in FIG. 1 is replaced with a liquid material vaporizer 302. In FIG. 11, the components other than the liquid material vaporizer 302 are the same as those of the film deposition apparatus shown in FIG. 1. Thus, in FIG. 11, the components having the same functions and structures as those shown in FIG. 1 are shown by the same reference numbers, and detailed description thereof is omitted.

The liquid material vaporizer 302 shown in FIG. 11 includes: a first liquid material vaporizer 304 configured to vaporize the liquid material supplied from the liquid-material supply source 110 so as to generate a source gas; and a second liquid material vaporizer 308 connected to a discharge opening for discharging the source gas generated by the first liquid material vaporizer 304, through a connection pipe 306. The source gas discharged from a discharge opening of the second liquid material vaporizer 308 is supplied to the film deposition chamber 200 through the source-gas supply pipe 132.

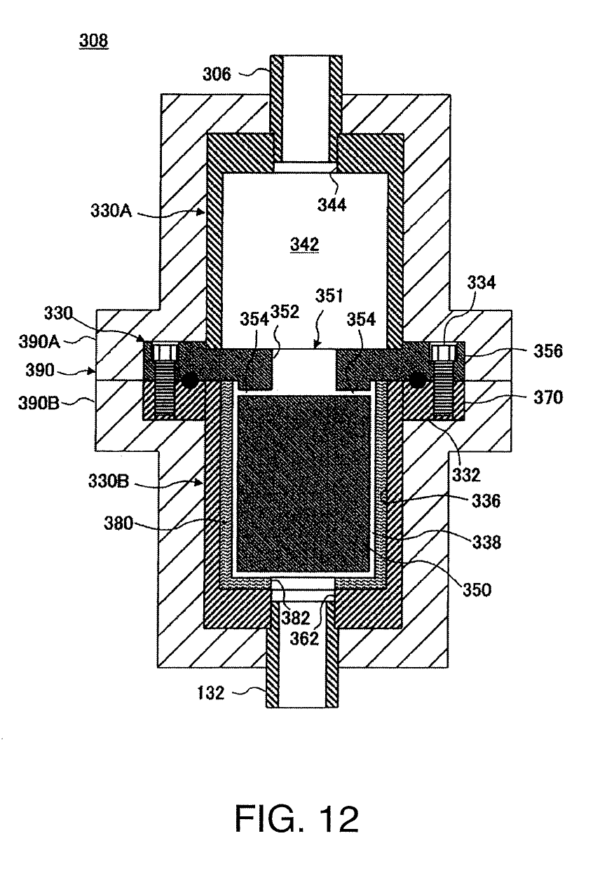

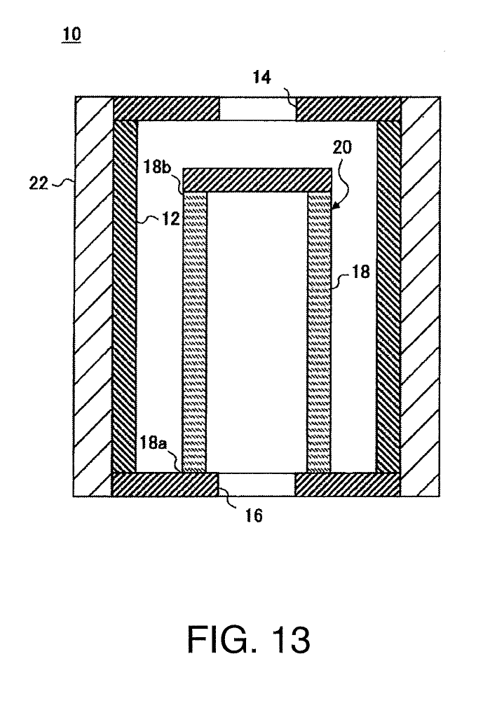

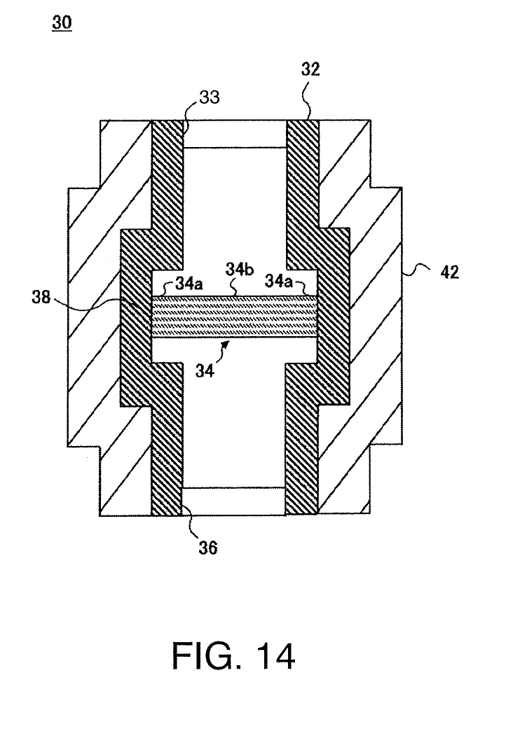

FIG. 12 shows a structural example of the second liquid material vaporizer 308. The second liquid material vaporizer 308 is composed only of the vaporizing part 300B of the liquid material vaporizer 300 shown in FIG. 2. In FIG. 12, the components having the same functions and structures as those shown in FIG. 2 are shown by the same reference numbers, and detailed description thereof is omitted. The connection pipe 306 is connected to the inlet port 344 of the second liquid material vaporizer 308, so that the source gas is introduced to the inlet port 344 from the discharge opening of the first liquid material vaporizer 304. This structure differs from the structure of the vaporizing part 300B shown in FIG. 2.

On the other hand, regardless of structure or type, any conventional liquid material vaporizer can serve as the first Liquid, material vaporizer 304, as long as the liquid material. vaporizer is configured to vaporize the liquid material supplied from the liquid-material supply source 110 so as to generate a source gas.

According to the second embodiment, in the second liquid material vaporizer 308, the entire breathable member as the mist trap member 380 can be uniformly heated and maintained at a high temperature. By causing the liquid material in a droplet state to collide with such a breathable member at a high speed, the vaporization efficiency can be significantly improved as compared with the conventional technique. In addition, since it is possible to prevent insufficient vaporization, which may be caused when the temperature of the breathable member is partially lowered, clogging of the breathable member can be prevented.

Although the preferred embodiments of the present invention have been described hereabove with reference to the drawings, the present invention is not limited to these examples. It is apparent that those skilled in the art can come up with various changes and modifications within the scope of claims, and it should be understood that such changes and modifications naturally fall in the scope of the present invention.

For example, the liquid material vaporizer according to the present invention can be applied to a liquid material vaporizer used in an MOCVD apparatus, a plasma CVD apparatus, an ALD (atomic layer deposition) apparatus, and an LP-CVD apparatus (irrespective of type such as a batch type, a vertical type, a horizontal type, and a mini-batch type).

In addition, in place of a breathable member, the mist trap member may be formed of any other member, such as a metal member having a roughened surface, as long as the member can trap the liquid material in a droplet state and efficiently carry out the heat exchange.

1. A liquid material vaporizer comprising a liquid-material supply part configured to make a liquid material into a droplet state and to discharge the same, and a vaporizing part configured to vaporize the liquid material in a droplet state so as to generate a source gas,
the vaporizing part including:
an inlet port to which the liquid material in a droplet state is introduced from the liquid-material supply part;
a housing body of a bottomed tubular shape, the housing body having an opening end on a side of the inlet port;
a columnar block having a flange for closing the opening end of the housing body, the columnar block being fitted in the housing body in such a manner that a gap serving as a vaporizing path is defined between the columnar block and an inside surface of the housing body;
a breathable mist trap member disposed in the vaporizing path formed between the inside surface of the housing body and an outside surface of the columnar block, in such a manner that the mist trap member is in contact with the inside surface of the housing body and covers the outside surface of the columnar block;
a heating part disposed to cover the housing body, the heating part being configured to heat the mist trap member through the housing body;
a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state, which has been introduced from the inlet port, toward an inside surface of the mist trap member; and
an outlet port disposed in a bottom part of the housing body, the outlet port being configured to deliver a source gas generated by the mist trap member that vaporizes the liquid material in a droplet state in the vaporizing path.

2. The liquid material vaporizer according to claim 1, wherein
a thickness of the mist trap member is smaller than a width of the vaporizing path, so that a gap in communication with the outlet port remains in the vaporizing path between the outside surface of the columnar block and the inside surface of the mist trap member.

3. The liquid material vaporizer according to claim 1, wherein
a thickness of the mist trap member is identical to a width of the vaporizing path, so that the mist trap member is disposed to fill the vaporizing path.

4. The liquid material vaporizer according to claim 1, wherein:
the mist trap member is composed of an outside mist trap member in contact with the inside surface of the housing body, and an inside mist trap member in contact with the outside surface of the columnar block; and
a gap in communication with the outlet port remains in the vaporizing path between an inside surface of the outside mist trap member and an outside surface of the inside mist trap member.

5. The liquid material vaporizer according to claim 1, wherein
the spout is composed of a bottomed hole formed in the end surface of the columnar block on the side of the inlet port, and a plurality of through holes radially extending from the bottomed hole as a center toward the outside surface of the columnar block to pass therethrough.

6. The liquid material vaporizer according to claim 5, wherein
the respective through hoes are formed perpendicularly to an axial direction of the columnar block.

7. The liquid material vaporizer according to claim 5, wherein
the respective through holes are formed in an inclined manner with respect to an axial direction of the columnar block.

8. The liquid material vaporizer according to claim 5, wherein
plural sets of the through holes, each set being composed of the through holes arranged to radially extend from the bottomed hole as a center perpendicularly to an axial direction of the columnar block, are arranged along the axial direction of the columnar block.

9. A liquid material vaporizer to be connected to another liquid material vaporizer configured to vaporize a liquid material so as to generate a source gas, the former liquid material vaporizer comprising:
an inlet port to which the source gas generated by the latter liquid material vaporizer is introduced;
a housing body of a bottomed tubular shape, the housing body having an opening end on a side of the inlet port;
a columnar block having a flange for closing the opening end of the housing body, the columnar block being fitted in the housing body in such a manner that a gap serving as a vaporizing path is defined between the columnar block and an inside surface of the housing body;
a breathable mist trap member disposed in the vaporizing path formed between the inside surface of the housing body and an outside surface of the columnar block, in such a manner that the mist trap member is in contact with the inside surface of the housing body and covers the outside surface of the columnar block;
a heating part disposed to cover the housing body, the heating part being configured to heat the mist trap member through the housing body;
a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state introduced from the inlet port toward an inside surface of the mist trap member; and
an outlet port disposed in a bottom part of the housing body, the outlet port being configured to deliver a source gas generated by the mist trap member that vaporizes the liquid material in a droplet state in the vaporizing path.

10. A film deposition apparatus comprising a film deposition chamber configured to perform a film deposition process to a substrate to be processed by introducing thereinto a source gas from a liquid material vaporizer,
the liquid material vaporizer comprising a liquid-material supply part configured to make a liquid material into a droplet state and to discharge the same, and a vaporizing part configured to vaporize the liquid material in a droplet state so as to generate a source gas, and
the vaporizing part including:
an inlet port to which the liquid material in a droplet state is introduced from the liquid-material supply part;
a housing body of a bottomed tubular shape, the housing body having an opening end on a side of the inlet port;
a columnar block having a flange for closing the opening end of the housing body, the columnar block being fitted in the housing body in such a manner that a gap serving as a vaporizing path is defined between the columnar block and an inside surface of the housing body;
a breathable mist trap member disposed in the vaporizing path formed between the inside surface of the housing body and an outside surface of the columnar block, in such a manner that the mist trap member is in contact with the inside surface of the housing body and covers the outside surface of the columnar block;
a heating part disposed to cover the housing body, the heating part being configured to heat the mist trap member through the housing body;
a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state, which has been introduced from the inlet port, toward an inside surface of the mist trap member; and
an outlet port disposed in a bottom part of the housing body, the outlet port being configured to deliver a source gas generated by the mist trap member that vaporizes the liquid material in a droplet state in the vaporizing path.

11. A film deposition apparatus comprising a film deposition chamber configured to perform a film deposition process to a substrate to be processed, by introducing thereinto a source gas from a liquid material vaporizer,
the liquid material vaporizer comprising a first liquid material vaporizer configured to vaporize a liquid material so as to generate a source gas, and a second liquid material vaporizer connected to the first liquid material vaporizer, and
the second liquid material vaporizer including:
an inlet port to which the source gas generated by the first liquid material vaporizer is introduced;
a housing body of a bottomed tubular shape, the housing body having an opening end on a side of the inlet port;
a columnar block having a flange for closing the opening end of the housing body, the columnar block being fitted in the housing body in such a manner that a gap serving as a vaporizing path is defined between the columnar block and an inside surface of the housing body;
a breathable mist trap member disposed in the vaporizing path formed between the inside surface of the housing body and an outside surface of the columnar block, in such a manner that the mist trap member is in contact with the inside surface of the housing body and covers the outside surface of the columnar block;
a heating part disposed to cover the housing body, the heating part being configured to heat the mist trap member through the housing body;
a spout formed in the columnar block in such a manner that the spout is in communication with the inlet port, and passes through the columnar block from an end surface of the columnar block on the side of the inlet port to a side surface of the columnar block, the spout being configured to spout the liquid material in a droplet state introduced from the inlet port toward an inside surface of the mist trap member; and
an outlet port disposed in a bottom part of the housing body, the outlet port being configured to deliver a source gas generated by the mist trap member that vaporizes the liquid material in a droplet state in the vaporizing path.
